(19) United States
(12) Patent Application Publication
(10) Pub. No.: US 2024/0006274 A1
(43) Pub. Date: Jan. 4, 2024

(54) SEMICONDUCTOR DEVICE

(71) Applicant: ROHM CO., LTD., Kyoto-shi (JP)

(72) Inventors: Ryohei UMENO, Kyoto-shi (JP); Hiroaki MATSUBARA, Kyoto-shi (JP); Yoshizo OSUMI, Kyoto-shi (JP); Tomohira KIKUCHI, Kyoto-shi (JP); Moe YAMAGUCHI, Kyoto-shi (JP)

(21) Appl. No.: 18/465,558

(22) Filed: Sep. 12, 2023

Related U.S. Application Data
(63) Continuation of application No. PCT/JP2022/007924, filed on Feb. 25, 2022.

(30) Foreign Application Priority Data
Mar. 19, 2021 (JP) 2021-045491

(51) Int. Cl. H01L 23/495; H01L 25/18; H01L 23/29; H01L 23/00

(52) U.S. Cl. CPC H01L 23/49555; H01L 23/49575; H01L 25/18; H01L 23/295; H01L 24/45; H01L 24/48; H01L 24/49; H01L 23/3121

(57) ABSTRACT

A semiconductor device includes: conductive members including first and second members; a first semiconductor element electrically connected to one conductive member; a second semiconductor element electrically connected to one conductive member configured to receive input of a voltage different from that applied to the first semiconductor element; and a sealing resin covering a part of each conductive member, the first semiconductor element, and the second semiconductor element. The voltage applied to the second member differs from the voltage applied to the first member. The sealing resin contains electrically insulating fillers. When a square cross section having a side length equal to ⅔ of a minimum spacing between two adjacent conductive members is hypothetically defined in the sealing resin, eight or more of the fillers each having a particle size equal to or greater than ⅛ of the minimum spacing are at least partially contained in the square cross section.

### TECHNICAL FIELD

The present disclosure relates to a semiconductor device with a plurality of semiconductor elements to which different voltages are applied.

### BACKGROUND ART

Semiconductor devices are used in inverter devices for electric vehicles (including hybrid vehicles) or household electrical appliances. Such an inverter device may include switching elements such as IGBTs (Insulated Gate Bipolar Transistor) or MOSFETs (Metal Oxide Semiconductor Field Effect Transistor) in addition to a semiconductor device. The semiconductor device includes a controller and a gate driver. In the inverter device, a control signal outputted from the outside is inputted to the controller of the semiconductor device. The controller converts the control signal into a PWM (Pulse Width Modulation) control signal and transmits it to the gate driver. Based on the PWM control signal, the gate driver drives e.g. six switching elements at appropriate timings. In this way, three-phase AC power for motor driving is obtained from DC power. An example of a semiconductor device (drive circuit) used in a motor drive device is disclosed in JP-A-2014-30049.

In some cases, the power supply voltage supplied to the controller and the power supply voltage supplied to the gate driver may differ from each other. In a semiconductor device with a plurality of semiconductor elements mounted in a single package, this results in a difference in power supply voltages applied to the two conductive paths, i.e., the conductive path to the controller and the conductive path to the gate driver. Therefore, a considerable spacing is provided between the conductive path to the controller and the conductive path to the gate driver, and the gap between the two conductive paths is filled with a sealing resin, to improve the dielectric strength of the semiconductor device. However, when the power supply voltages applied to the two conduction paths are significantly different, further measures may need to be taken to improve the dielectric strength.

### BRIEF DESCRIPTION OF THE DRAWINGS

FIG. 1 is a plan view of a semiconductor device according to a first embodiment of the present disclosure.

FIG. 2 is a plan view corresponding to FIG. 1, as seen through a sealing resin.

FIG. 3 is a front view of the semiconductor device shown in FIG. 1.

FIG. 4 is a left side view of the semiconductor device shown in FIG. 1.

FIG. 5 is a right side view of the semiconductor device shown in FIG. 1.

FIG. 6 is a sectional view taken along line VI-VI in FIG. 2.

FIG. 7 is a sectional view taken along line VII-VII in FIG. 2.

FIG. 8 is an enlarged view showing a part of FIG. 2.

FIG. 9 is a sectional view taken along line IX-IX in FIG. 8.

FIG. 10 is an enlarged view showing a part of FIG. 6.

FIG. 11 is a plan view of a semiconductor device according to a second embodiment of the present disclosure, as seen through a sealing resin.

FIG. 12 is a sectional view taken along line XII-XII in FIG. 11.

### DETAILED DESCRIPTION OF EMBODIMENTS

The following describes preferred embodiments of the present disclosure with reference to the drawings.

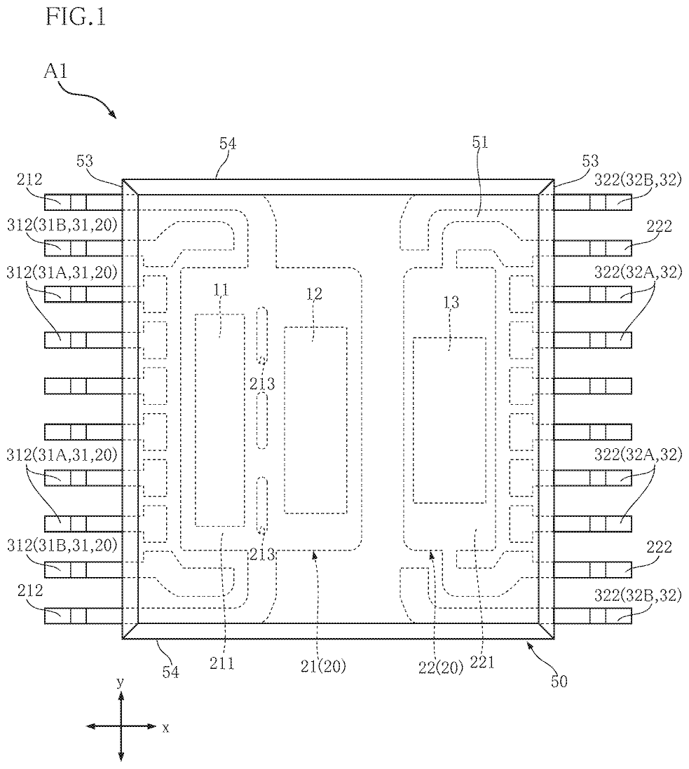

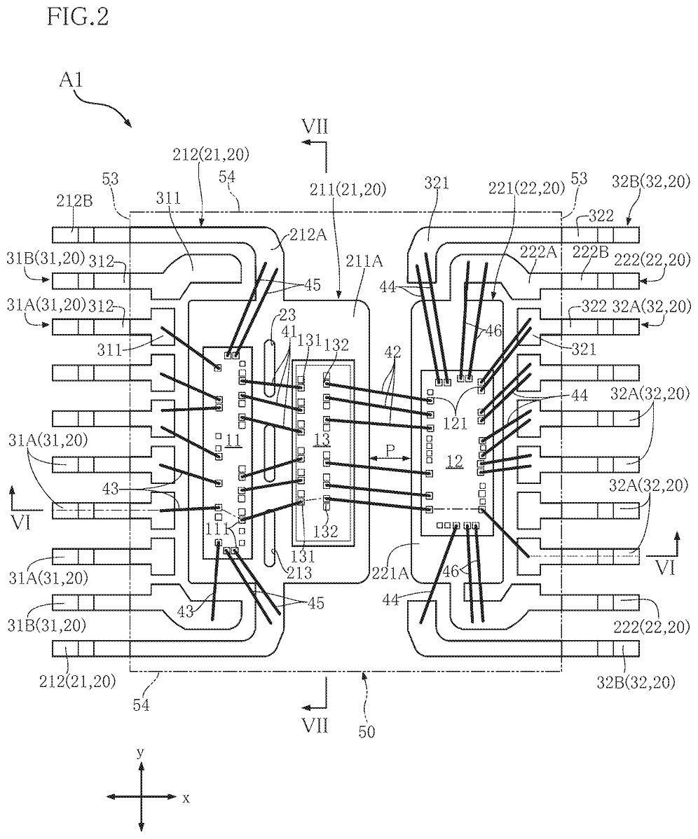

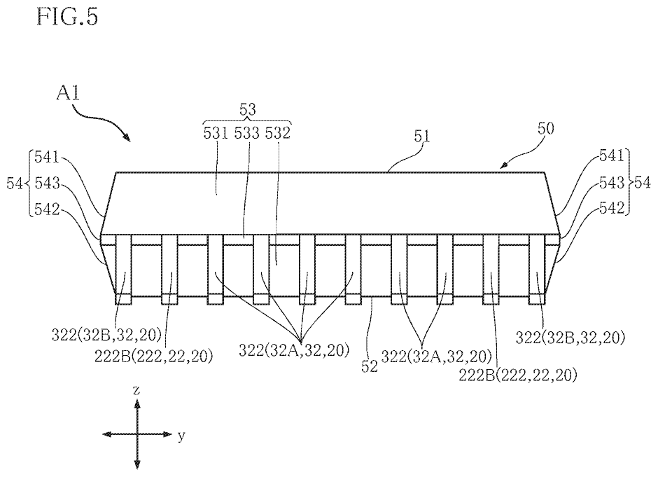

A semiconductor device A1 according to a first embodiment of the present disclosure is described below with reference to FIGS. 1 to 10. The semiconductor device A1 includes a first semiconductor element 11, a second semiconductor element 12, an insulating element 13, a plurality of conductive members 20, a plurality of first wires 41, a plurality of second wires 42, a plurality of third wires 43, a plurality of fourth wires 44, a plurality of fifth wires 45, a plurality of sixth wires 46 and a sealing resin 50. The conductive members 20 include a first member 21, a second member 22, a plurality of first terminals 31 and a plurality of second terminals 32. The semiconductor device A1 is configured to be surface-mounted on a wiring board of an inverter device of e.g. a vehicle such as an electric vehicle or a hybrid vehicle. The semiconductor device A1 is of a SOP (Small Outline Package) type. The package type of the semiconductor device A10 is not limited to the SOP. For convenience of understanding, the sealing resin 50 is transparent in FIG. 2. In FIG. 2, the outlines of the sealing resin 50 is shown by imaginary lines (two-dot chain lines).

In the description of the semiconductor device A1, the thickness direction of each of the first semiconductor element 11 and the second semiconductor element 12 is defined as the “thickness direction z”. A direction orthogonal to the thickness direction z is defined as the “first direction x”. The direction orthogonal to the thickness direction z and the first direction x is defined as the “second direction y”.

The first semiconductor element 11, the second semiconductor element 12 and the insulating element 13 are the core components for the functions of the semiconductor device A1. In the semiconductor device A1, the first semiconductor element 11, the second semiconductor element 12 and the insulating element 13 are individual elements. In the first direction x, the second semiconductor element 12 is located on the opposite side of the first semiconductor element 11 relative to the insulating element 13. As viewed in the thickness direction z, each of the first semiconductor element 11, the second semiconductor element 12 and the insulating element 13 has a rectangular shape with the long side in the second direction y.

The first semiconductor element 11 is a controller (a controlling element) for a gate driver that drives switching elements such as IGBTs or MOSFETs. The first semiconductor element 11 includes a circuit for converting control signals inputted from e.g. an ECU into PWM control signals, a transmission circuit for transmitting the PWM control signals to the second semiconductor element 12, and a receiving circuit for receiving electric signals from the second semiconductor element 12.

The second semiconductor element 12 is a gate driver (a driving element) for driving the switching elements. The second semiconductor element 12 includes a receiving circuit for receiving PWM control signals, a circuit for driving the switching elements based on the PWM control signals, and a transmission circuit for transmitting electric signals to the first semiconductor element 11. Examples of the electric signals include an output signal from a temperature sensor disposed near the motor.

The insulating element 13 is an element that transmits PWM control signals and other electric signals in an insulated condition. In the semiconductor device A1, the insulating element 13 is of an inductive type. An example of the inductive type insulating element 13 is an insulation transformer. An insulation transformer includes two inductively coupled inductors (coils) to realize transmission of electric signals in an insulated state. The insulating element 13 has a substrate made of silicon. Inductors made of copper (Cu) are formed on the substrate. The inductors include a transmitting-side inductor and a receiving-side inductor, which are stacked in the thickness direction z. A dielectric layer made of silicon dioxide (SiO₂), for example, is interposed between the transmitting-side inductor and the receiving-side inductor. The dielectric layer provides electrical insulation between the transmitting-side inductor and the receiving-side inductor. Alternatively, the insulating element 13 may be of a capacitive type. An example of a capacitive insulating element 13 is a capacitor. The insulating element 13 may be a photocoupler.

In the semiconductor device A1, the voltage applied to the first semiconductor element 11 and the voltage applied to the second semiconductor element 12 are different from each other. Thus, there is a potential difference between the first semiconductor element 11 and the second semiconductor element 12. In the semiconductor device A1, the power supply voltage supplied to the second semiconductor element 12 is higher than that supplied to the first semiconductor element 11.

In the semiconductor device A1, therefore, the insulating element 13 provides insulation between a first circuit including the first semiconductor element 11 as a component and a second circuit including the second semiconductor element 12 as a component. The components of the first circuit include the first member 21, the first terminals 31, the first wires 41, the third wires 43 and the fifth wires 45, in addition to the first semiconductor element 11. The components of the second circuit include the second member 22, the second terminals 32, the second wires 42, the fourth wires 44 and the sixth wires 46, in addition to the second semiconductor element 12. The first circuit and the second circuit have different potentials. In the semiconductor device A1, the potential of the second circuit is higher than the potential of the first circuit. In this state, the insulating element 13 relays signals between the first circuit and the second circuit. For example, in an inverter device for an electric vehicle or a hybrid vehicle, the voltage applied to the ground of the second semiconductor element 12 may transiently become 600 V or higher while the voltage applied to the ground of the first semiconductor element 11 is about 0 V.

As shown in FIGS. 2 and 6, the first semiconductor element 11 has a plurality of first electrodes 111. The first electrodes 111 are on the upper surface of the first semiconductor element 11 (i.e., the surface facing in the same direction as a first mounting surface 211A of a first island portion 211 of the first member 21 described later). The composition of the first electrodes 111 includes aluminum (Al), for example. In other words, each first electrode 111 contains aluminum. The first electrodes 111 are electrically connected to the circuit formed in the first semiconductor element 11.

As shown in FIGS. 2 and 6, the insulating element 13 is located between the first semiconductor element 11 and the second semiconductor element 12 in the first direction x. A plurality of first relay electrodes 131 and a plurality of second relay electrodes 132 are provided on the upper surface (the surface facing in the same direction as the first mounting surface 211A described above) of the insulating element 13. Each of the first relay electrodes 131 and the second relay electrodes 132 is electrically connected to the transmitting-side inductor or the receiving-side inductor. The first relay electrodes 131 are arranged along the second direction y and located closer to the first semiconductor element 11 than is the second semiconductor element 12 in the first direction x. The second relay electrodes 132 are arranged along the second direction y and located closer to the second semiconductor element 12 than is the first semiconductor element 11 in the first direction x.

As shown in FIGS. 2 and 6, the second semiconductor element 12 has a plurality of second electrodes 121. The second electrodes 121 are on the upper surface of the second semiconductor element 12 (i.e., the surface facing in the same direction as a second mounting surface 221A of a second island portion 221 of the second member 22 described later). The composition of the second electrode 121 includes aluminum, for example. The second electrodes 121 are electrically connected to the circuit formed in the second semiconductor element 12.

The conductive members 20 form conduction paths between the wiring board on which the semiconductor device A1 is mounted and the first semiconductor element 11, the insulating element 13 and the second semiconductor element 12. The conductive members 20 are formed from a same lead frame. The lead frame contains copper in its composition. As described above, the conductive members 20 include the first member 21, the second member 22, the first terminals 31 and the second terminals 32.

As shown in FIGS. 1 and 2, the first member 21 and the second member 22 are spaced apart from each other in the first direction x. In the semiconductor device A1, the first semiconductor element 11 and the insulating element 13 are mounted on the first member 21, and the second semiconductor element 12 is mounted on the second member 22. The voltage applied to the second member 22 differs from the voltage applied to the first member 21. In the semiconductor device A1, the voltage applied to the second member 22 is higher than the voltage applied to the first member 21.

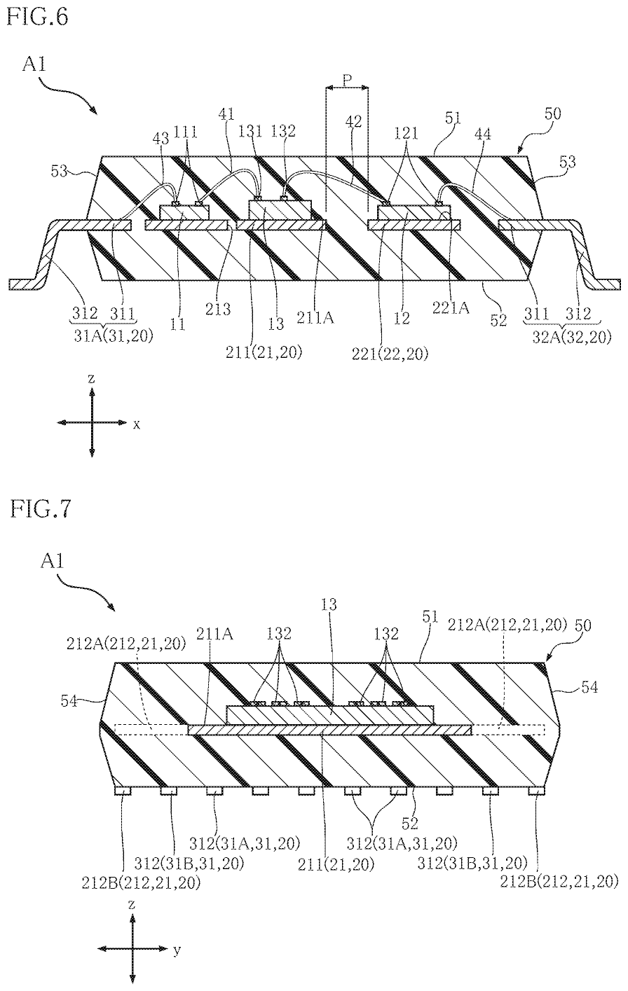

As shown in FIG. 2, the first member 21 has the first island portion 211 and two first suspension lead portions 212. As shown in FIGS. 6 and 7, the first island portion 211 has a first mounting surface 211A facing in the thickness direction z. In the semiconductor device A1, the first semiconductor element 11 and the insulating element 13 are mounted on the first mounting surface 211A. The first semiconductor element 11 and the insulating element 13 are bonded to the first mounting surface 211A via a conductive bonding material (such as solder or metal paste) not shown. The first island portion 211 is covered with the sealing resin 50. The thickness of the first island portion 211 is equal to or greater than 100 μm and equal to or less than 300 μm, for example.

As shown in FIGS. 2 and 6, the first island portion 211 is formed with a plurality of through-holes 213. Each of the through-holes 213 penetrates the first island portion 211 in the thickness direction z and extends along the second direction y. As viewed in the thickness direction z, at least one of the through-holes 213 is located between the first semiconductor element 11 and the insulating element 13. The through-holes 213 are arranged along the second direction y.

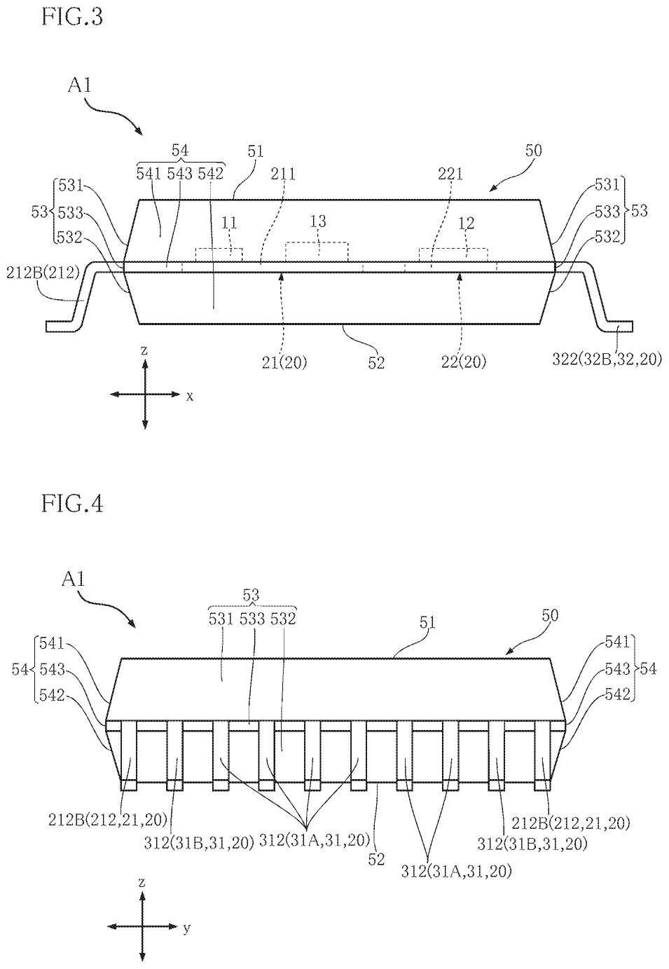

As shown in FIG. 2, the two first suspension lead portions 212 extend outward from opposite ends in the second direction y of the first island portion 211. The two first suspension lead portions 212 are spaced apart from each other in the second direction y. At least one of the two first suspension lead portions 212 is electrically connected to the ground of the first semiconductor element 11 via a fifth wire 45. Each of the two first suspension lead portions 212 has a covered portion 212A and an exposed portion 212B. The covered portion 212A is connected to the first island portion 211 and covered with the sealing resin 50. The exposed portion 212B is connected to the covered portion 212A and exposed from the sealing resin 50. As viewed in the thickness direction z, the exposed portion 212B extends along the first direction x. As shown in FIG. 3, the exposed portion 212B is bent into a gull-wing profile as viewed in the second direction y. The surface of the exposed portion 212B may be plated with tin (Sn), for example.

As shown in FIG. 2, the second member 22 has the second island portion 221 and two second suspension lead portions 222. As shown in FIG. 6, the second island portion 221 has a second mounting surface 221A facing in the thickness direction z. In the semiconductor device A1, the second semiconductor element 12 is mounted on the second mounting surface 221A. The second semiconductor element 12 is bonded to the second mounting surface 221A via a conductive bonding material (such as solder or metal paste) not shown. The second island portion 221 is covered with the sealing resin 50. The thickness of the second island portion 221 is equal to or greater than 100 μm and equal to or less than 300 μm, for example. As viewed in the first direction x, the second island portion 221 overlaps with the first island portion 211 of the first member 21.

As shown in FIG. 2, the two second suspension lead portions 222 extend outward from opposite ends in the second direction y of the second island portion 221. The two second suspension lead portions 222 are spaced apart from each other in the second direction y. At least one of the two second suspension lead portions 222 is electrically connected to the ground of the second semiconductor element 12 via a sixth wire 46. Each of the two second suspension lead portions 222 has a covered portion 222A and an exposed portion 222B. The covered portion 222A is connected to the second island portion 221 and covered with the sealing resin 50. The exposed portion 222B is connected to the covered portion 222A and exposed from the sealing resin 50. As viewed in the thickness direction z, the exposed portion 222B extends along the first direction x. As shown in FIG. 3, the exposed portion 222B is bent into a gull-wing profile as viewed in the second direction y. The surface of the exposed portion 222B may be plated with tin (Sn), for example.

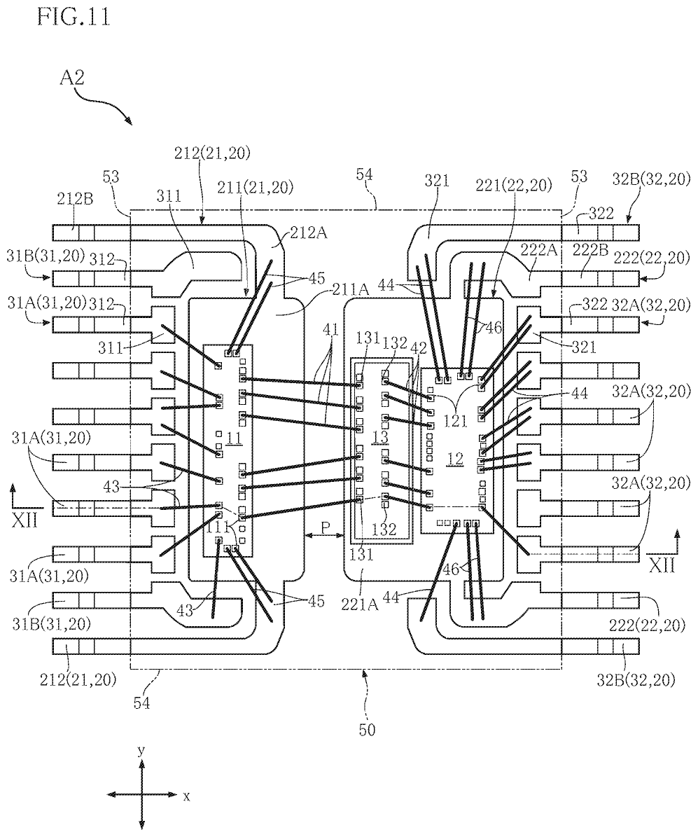

As shown in FIGS. 2 and 6, the first island portion 211 of the first member 21 and the second island portion 221 of the second member 22 are spaced apart from each other in the first direction x with a spacing P. As shown in FIG. 10, the spacing P is the minimum distance between the first island portion 211 and the second island portion 221.

As shown in FIGS. 1 and 2, the first terminals 31 are located on one side in the first direction x. Specifically, the first terminals 31 are located on the opposite side of the second island portion 221 of the second member 22 relative to the first island portion 211 of the first member 21 in the first direction x. The first terminals 31 are arranged along the second direction y. At least one of the first terminals 31 is electrically connected to the first semiconductor element 11 via a third wire 43. The first terminals 31 include a plurality of first intermediate terminals 31A and two first-side terminals 31B. The two first-side terminals 31B flank the first intermediate terminals 31A in the second direction y. Each of the two first-side terminals 31B is located between one of the two first suspension lead portions 212 of the first member 21 and the first intermediate terminal 31A closest to the first suspension lead portion 212 in the second direction y.

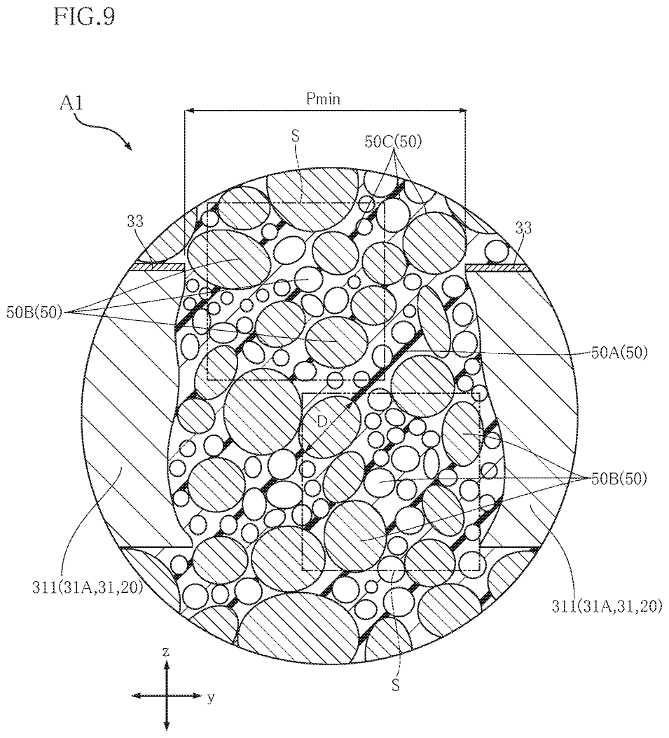

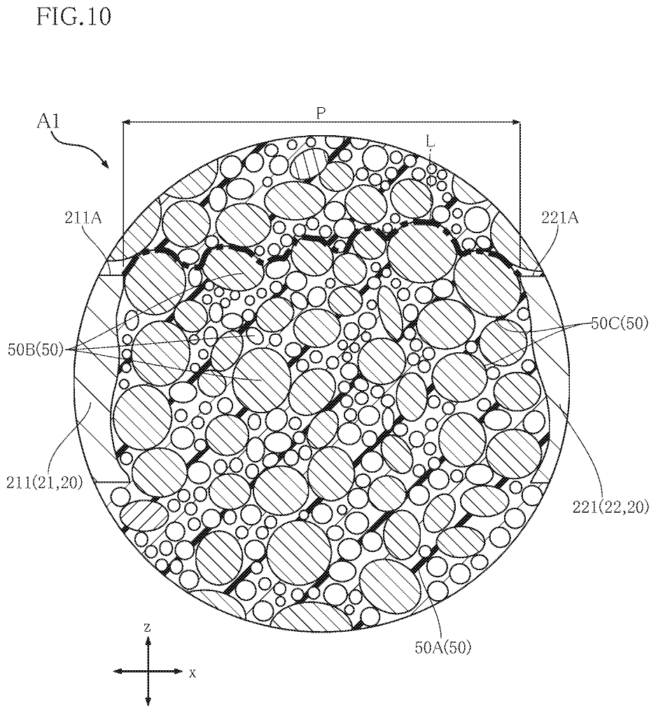

As shown in FIGS. 2 and 6, each of the first terminals 31 has a covered portion 311 and an exposed portion 312. The covered portions 311 are covered with the sealing resin 50. The dimension of the covered portion 311 of each of the two first-side terminals 31B in the first direction x is larger than the dimension of the covered portion 311 of each of the first intermediate terminals 31A in the first direction x. As shown in FIG. 9, each covered portion 311 has a metal layer 33. The metal layer 33 is located on one side of the covered portion 311 in the thickness direction z (i.e., the side which the first mounting surface 211A of the first island portion 211 of the first member 21 faces). The metal layer 33 is in contact with the sealing resin 50. The composition of the metal layer 33 includes silver.

As shown in FIGS. 2 and 6, the exposed portions 312 are connected to the covered portions 311 and exposed from the sealing resin 50. As viewed in the thickness direction z, the exposed portions 312 extend along the first direction x. The exposed portions 312 are bent into a gull-wing profile as viewed in the second direction y. The shape of each exposed portion 312 is the same as the exposed portion 212B of each of the two first suspension lead portions 212 of the first member 21. The surface of the exposed portion 312 may be plated with tin, for example.

As shown in FIGS. 1 and 2, the second terminals 32 are located on the other side in the first direction x. Specifically, the second terminals 32 are located on the opposite side of the first terminals 31 relative to the first island portion 211 of the first member 21 in the first direction x. The second terminals 32 are arranged along the second direction y. At least one of the second terminals 32 is electrically connected to the second semiconductor element 12 via a fourth wire 44. The second terminals 32 include a plurality of second intermediate terminals 32A and two second-side terminals 32B. The two second-side terminals 32B flank the second intermediate terminals 32A in the second direction y. In the second direction y, each of the two second suspension lead portions 222 of the second member 22 is located between one of the two second-side terminals 32B and the second intermediate terminal 32A closest to the second-side terminal 32B.

As shown in FIGS. 2 and 6, each of the second terminals 32 has a covered portion 321 and an exposed portion 322. The covered portions 321 are covered with the sealing resin 50. The dimension of the covered portion 321 of each of the two second-side terminals 32B in the first direction x is larger than the dimension of the covered portion 321 of each of the second intermediate terminals 32A in the first direction x. As with the covered portions 311 of the first terminals 31, each covered portion 321 has a metal layer 33 shown in FIG. 9. The metal layer 33 is located on one side of the covered portion 321 in the thickness direction z (i.e., the side which the second mounting surface 221A of the second island portion 221 of the second member 22 faces). The metal layer 33 is in contact with the sealing resin 50.

As shown in FIGS. 2 and 6, the exposed portions 322 are connected to the covered portions 321 and exposed from the sealing resin 50. As viewed in the thickness direction z, the exposed portions 322 extend along the first direction x. As shown in FIG. 3, the exposed portions 322 are bent into a gull-wing profile as viewed in the second direction y. The shape of each exposed portion 322 is the same as the exposed portion 222B of each of the two second suspension lead portions 222 of the second member 22. The surface of the exposed portion 322 may be plated with tin, for example.

The first wires 41, the second wires 42, the third wires 43, the fourth wires 44, the fifth wires 45 and the sixth wires 46 form, together with the conductive members 20, conduction paths for the first semiconductor element 11, the second semiconductor element 12 and the insulating element 13 to perform predetermined functions.

As shown in FIGS. 2 and 6, each of the first wires 41 is bonded to one of the first relay electrodes 131 of the insulating element 13 and one of the first electrodes 111 of the first semiconductor element 11. Thus, the first semiconductor element 11 and the insulating element 13 are electrically connected to each other. The first wires 41 are arranged along the second direction y. The composition of the first wires 41 includes gold (Au).

As shown in FIGS. 2 and 6, each of the second wires 42 is bonded to one of the second relay electrodes 132 of the insulating element 13 and one of the second electrodes 121 of the second semiconductor element 12. Thus, the second semiconductor element 12 and the insulating element 13 are electrically connected to each other. The second wires 42 are arranged along the second direction y. In the semiconductor device A1, the second wires 42 extend across the gap between the first island portion 211 of the first member 21 and the second island portion 221 of the second member 22. The composition of the second wires 42 includes gold.

As shown in FIGS. 2 and 6, each of the third wires 43 is bonded to one of the first electrodes 111 of the first semiconductor element 11 and the covered portion 311 of one of the first terminals 31. Thus, at least one of the first terminals 31 is electrically connected to the first semiconductor element 11. The composition of the third wires 43 includes gold. Alternatively, the composition of the third wires 43 may include copper.

As shown in FIGS. 2 and 6, each of the fourth wires 44 is bonded to one of the second electrodes 121 of the second semiconductor element 12 and the covered portion 321 of one of the second terminals 32. Thus, at least one of the second terminals 32 is electrically connected to the second semiconductor element 12. The composition of the fourth wires 44 includes gold. Alternatively, the composition of the fourth wires 44 may include copper.

As shown in FIG. 2, each of the fifth wires 45 is bonded to one of the first electrodes 111 of the first semiconductor element 11 and the covered portion 212A of one of the two first suspension lead portions 212 of the first member 21. Thus, the first semiconductor element 11 is electrically connected to the first member 21. The composition of the fifth wires 45 includes gold. Alternatively, the composition of the fifth wires 45 may include copper.

As shown in FIG. 2, each of the sixth wires 46 is bonded to one of the second electrodes 121 of the second semiconductor element 12 and the covered portion 222A of one of the two second suspension lead portions 222 of the second member 22. Thus, the second semiconductor element 12 is electrically connected to the second member 22. The composition of the sixth wires 46 includes gold. Alternatively, the composition of the sixth wires 46 may include copper.

As shown in FIG. 1, the sealing resin 50 covers the first semiconductor element 11, the second semiconductor element 12, the insulating element 13 and a part of each of the conductive members 20. The sealing resin 50 also covers the first wires 41, the second wires 42, the third wires 43, the fourth wires 44, the fifth wires 45 and the sixth wires 46. The sealing resin 50 is electrically insulating. The sealing resin 50 insulates the first member 21 and the second member 22 from each other. As shown in FIG. 9, the sealing resin 50 contains fillers 50B. The fillers 50B are electrically insulating. The sealing resin 50 is rectangular as viewed in the thickness direction z.

As shown in FIGS. 3 to 5, the sealing resin 50 has a top surface 51, a bottom surface 52, a pair of first side surfaces 53 and a pair of second side surfaces 54.

As shown in FIGS. 3 to 5, the top surface 51 and the bottom surface 52 are spaced apart from each other in the thickness direction z. The top surface 51 and the bottom surface 52 face away from each other in the thickness direction z. Each of the top surface 51 and the bottom surface 52 is flat (or generally flat).

As shown in FIGS. 3 to 5, the pair of first side surfaces 53 are connected to the top surface 51 and the bottom surface 52 and spaced apart from each other in the first direction x. The exposed portions 212B of the two first suspension lead portions 212 of the first member 21 and the exposed portions 312 of the first terminals 31 are exposed from one of the pair of first side surfaces 53 that is located on one side in the first direction x. The exposed portions 222B of the two second suspension lead portions 222 of the second member 22 and the exposed portions 322 of the second terminals 32 are exposed from the other one of the first side surfaces 53 that is located on the other side in the first direction x.

As shown in FIGS. 3 to 5, each of the pair of first side surfaces 53 includes a first upper portion 531, a first lower portion 532 and a first intermediate portion 533. The first upper portion 531 is connected to the top surface 51 on one side in the thickness direction z and connected to the first intermediate portion 533 on the other side in the thickness direction z. The first upper portion 531 is inclined with respect to the top surface 51. The first lower portion 532 is connected to the bottom surface 52 on one side in the thickness direction z and connected to the first intermediate portion 533 on the other side in the thickness direction z. The first lower portion 532 is inclined with respect to the bottom surface 52. The first intermediate portion 533 is connected to the first upper portion 531 on one side in the thickness direction z and connected to the first lower portion 532 on the other side in the thickness direction z. The in-plane direction of the first intermediate portion 533 may be defined by the thickness direction z and the second direction y. The first intermediate portion 533 is located outside the top surface 51 and the bottom surface 52 as viewed in the thickness direction z. The exposed portions 212B of the two first suspension lead portions 212 of the first member 21, the exposed portions 222B of the two second suspension lead portions 222 of the second member 22, the exposed portions 312 of the first terminals 31 and the exposed portions 322 of the second terminals 32 are exposed from the first intermediate portions 533 of the pair of first side surfaces 53.

As shown in FIGS. 3 to 5, the pair of second side surfaces 54 are connected to the top surface 51 and the bottom surface 52 and spaced apart from each other in the second direction y. As shown in FIG. 1, the first member 21, the second member 22, the first terminals 31 and the second terminals 32 are spaced apart from the pair of second side surfaces 54.

As shown in FIGS. 3 to 5, each of the pair of second side surfaces 54 includes a second upper portion 541, a second lower portion 542 and a second intermediate portion 543. The second upper portion 541 is connected to the top surface 51 on one side in the thickness direction z and connected to the second intermediate portion 543 on the other side in the thickness direction z. The second upper portion 541 is inclined with respect to the top surface 51. The second lower portion 542 is connected to the bottom surface 52 on one side in the thickness direction z and connected to the second intermediate portion 543 on the other side in the thickness direction z. The second lower portion 542 is inclined with respect to the bottom surface 52. The second intermediate portion 543 is connected to the second upper portion 541 on one side in the thickness direction z and connected to the second lower portion 542 on the other side in the thickness direction z. The in-plane direction of the second intermediate portion 543 may be defined by the thickness direction z and the first direction x. The second intermediate portion 543 is located outside the top surface 51 and the bottom surface 52 as viewed in the thickness direction z.

As shown in FIGS. 9 and 10, the sealing resin 50 includes a base material 50A and fillers 50B. The base material 50A mainly contains epoxy resin and a curing agent. The composition of the fillers 50B includes silicon dioxide. In the semiconductor device A1, the fillers 50B account for about 90% of the sealing resin 50 by weight.

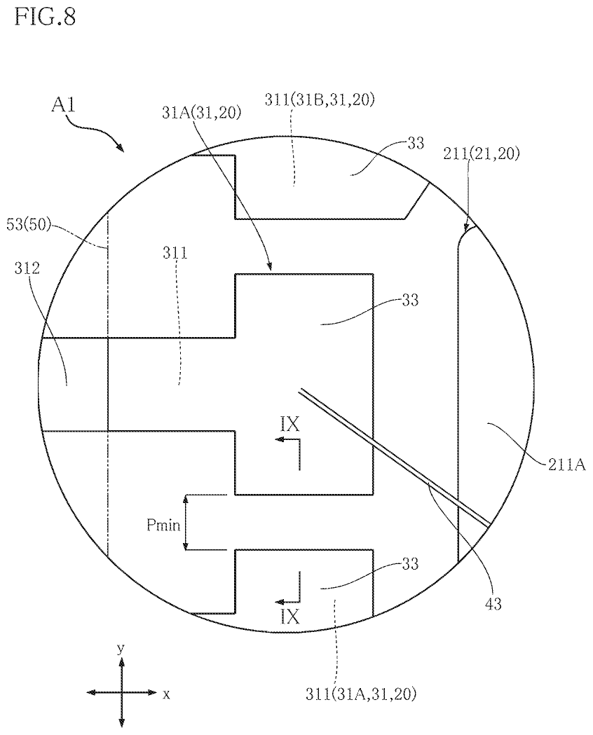

When a square cross section S is hypothetically defined in the sealing resin 50 as shown in FIG. 9, eight or more fillers 50B, each having a particle size D equal to or greater than a reference value, are at least partially contained in the square cross section S. The particle size D refers to the maximum diameter of each filler 50B in the square cross section S. In FIGS. 9 and 10, the fillers 50B having a particle size D equal to or greater than the reference value are indicated by oblique lines. The square cross section S extends across the sealing resin 50 alone. The position of the square cross section S in the sealing resin 50 is not limited. The length of a side of the square cross section S and the reference value for the particle size D of the fillers 50B are defined based on the minimum spacing Pmin shown in FIG. 8. The minimum spacing Pmin is the smallest value of the spacings between two adjacent conductive members 20 of the plurality of conductive members 20. In the semiconductor device A1, the minimum spacing Pmin is the smaller one of the two values: the smallest value of the spacings between two adjacent first terminals 31 in the second direction y; and the smallest value of the spacings between two adjacent second terminals 32 in the second direction y. In the semiconductor device A1, the minimum spacing Pmin is 150 μm.

The length of a side of the square cross section S hypothetically defined in the sealing resin 50 is equal to ⅔ of the minimum spacing Pmin. In the semiconductor device A1, the length of a side of the square cross section S is 100 μm. The reference value for the particle size D of the fillers 50B is equal to ⅛ of the minimum spacing Pmin. In the semiconductor device A1, the reference value for the particle size D is 18.75 μm. It can be said from the above that in the semiconductor device A1, eight or more fillers 50B each having a particle size D equal to or greater than 18.75 μm are at least partially contained in the square cross section S with a side length of 100 μm. Additionally, the maximum value of the particle sizes D of the fillers 50B is ½ of the minimum spacing Pmin. In the semiconductor device A1, therefore, the maximum particle size D of the fillers 50B is 75 μm.

The position of the square cross section S in the sealing resin 50 can vary. Thus, as will be understood from FIG. 9, the particle size distribution of the fillers 50B in the square cross section S is uniform across the sealing resin 50. Additionally, the spacing P between the first member 21 (first island portion 211) and the second member 22 (second island portion 221) shown in FIG. 10 is equal to or greater than 1.0 times and equal to or less than 3.0 times the minimum spacing Pmin.

Generally, in motor driver circuits of inverter devices, a half-bridge circuit that includes a low-side (low-potential side) switching element and a high-side (high-potential side) switching element is configured. An example in which these switching elements are MOSFETs is described below. In the low-side switching element, the reference potentials of the source of the switching element and the gate driver that drives the switching device are both ground. On the other hand, in the high-side switching element, the reference potentials of the source of the switching element and the gate driver that drives the switching element both correspond to the potential at the output node of the half-bridge circuit. Because the potential at the output node changes in response to the operation of the high-side switching element and the low-side switching elements, the reference potential of the gate driver that drives the high-side switching element changes. When the high-side switching element is ON, the reference potential is equivalent to the voltage applied to the drain of the high-side switching element (e.g., 600 V or higher). In semiconductor device A1, the ground of the first semiconductor element 11 and the ground of the second semiconductor element 12 are separated. Thus, when the semiconductor device A1 is used as a gate driver for driving the high-side switching element, a voltage equivalent to the voltage applied to the drain of the high-side switching element is transiently applied to the ground of the second semiconductor element 12.

The effect and advantages of the semiconductor device A1 are described below.

The semiconductor device A1 has the plurality of conductive members 20 including the first member 21 and the second member 22 and the sealing resin 50 covering a part of each of the conductive members 20. The voltage applied to the second member 22 differs from the voltage applied to the first member 21. The sealing resin 50 contains fillers 50B that are electrically insulating. The square cross section S in the sealing resin 50, which has a side length of ⅔ of the minimum spacing Pmin between two adjacent conductive members 20, contains at least portions of eight or more fillers 50B each having a particle size D equal to or greater than ⅛ of the minimum spacing Pmin.

It has been confirmed that dielectric breakdown of the semiconductor device A1 can occur at the interfaces 50C between the base material 50A and the fillers 50B in the sealing resin 50 shown in FIG. 9. Further, the probability of dielectric breakdown of the semiconductor device A1 is extremely high at the sealing resin 50 that fills the spacing P between the first member 21 and the second member 22, to which different voltages are applied. Dielectric breakdown occurs when a charged carrier moves from one conductive member 20 to another conductive member 20 of two adjacent conductive members 20 through the sealing resin 50 filling the gap between these conductive members 20. Such a carrier travels along the interfaces between the base material 50A and the fillers 50B in the sealing resin 50. As shown in FIG. 10, with the semiconductor device A1 having the configuration described above, the travel distance L of the carrier from the second mounting surface 221A of the second island portion 221 (the second member 22) to the first mounting surface 211A of the first island portion 211 (the first member 21) is increased. Therefore, it takes longer time for the semiconductor device A1 to reach dielectric breakdown. Thus, the semiconductor device A1 can further improve the dielectric strength.

The length of a side of the square cross section S of the sealing resin 50 and the reference value for the particle size D of the fillers 50B in the sealing resin 50 are defined based on the minimum spacing Pmin of two adjacent conductive members of the plurality of conductive members 20. The fillers 50B having a particle size D equal to or greater than the reference value do not include fillers 50B that do not contribute to the improvement of the dielectric strength of the semiconductor device A1. Moreover, the maximum value of the particle sizes D of the fillers 50B is ½ of the minimum spacing Pmin. With such a configuration, the fluidized sealing resin 50 flows smoothly between two adjacent conductive members 20 during the manufacture of semiconductor device A1, so that poor filling of the sealing resin 50 is prevented.

In the semiconductor device A1, the spacing P between the first member 21 and the second member 22 is important for further improvement of the dielectric strength of the semiconductor device A1. It is preferable that the spacing P is equal to or greater than 1.0 times and equal to or less than 3.0 times the minimum spacing Pmin of two adjacent conductive members 20 of the plurality of conductive members 20. The spacing P exceeding 3.0 times the minimum spacing Pmin contributes to further improvement of the dielectric strength of the semiconductor device A1 but may cause an increase in size of the semiconductor device A1, which is not desirable.

In the semiconductor device A1, each of the conductive members 20 is partially exposed at either one of the pair of first side surfaces 53 of the sealing resin 50. Such a configuration is realized by exposing the two first suspension lead portions 212 of the first member 21 at one side of the sealing resin 50 in the first direction x and exposing the second suspension lead portions 222 of the second member 22 at the other side of the sealing resin 50 in the first direction x. With such a configuration, the conductive members 20 are spaced apart from the pair of second side surfaces 54 of the sealing resin 50. Thus, in the semiconductor device A1, metal parts such as an island support are not exposed at the second side surfaces 54. This can improve the dielectric strength of the semiconductor device A1.

In the semiconductor device A1, the first island portion 211 of the first member 21, which is larger in area than the second island portion 221 of the second member 22, is formed with the through-holes 213. During the manufacture of the semiconductor device A1, the fluidized sealing resin 50 passes through the through-holes 213, so that poor filling of the sealing resin 50 is prevented. Thus, generation of voids in the sealing resin 50 is effectively reduced or eliminated. This contributes to the prevention of a decrease in the dielectric strength of the semiconductor device A1.

The semiconductor device A1 also includes the first wires 41 and the second wires 42. The first wires 41 are bonded to the insulating element 13 and the first semiconductor element 11. The second wires 42 are bonded to the insulating element 13 and the second semiconductor element 12. The composition of the first wires 41 and the second wires 42 includes gold. In forming a first wire 41, the first bonding portion of the first wire 41 is formed on a first relay electrode 131 of the insulating element 13, and the last bonding portion of the first wire 41 is formed on one of the first terminals 31 or one of the two first suspension lead portions 212 of the first member 21. By this, the first wire 41 can be shaped such that the distance in the thickness direction z between the top of the first wire 41 closest to the top surface 51 of the sealing resin 50 and the insulating element 13 is as long as possible. Similarly, in forming a second wire 42, the first bonding portion of the second wire 42 is formed on a second relay electrode 132 of the insulating element 13, and the last bonding portion of the second wire 42 is formed on one of the second terminals 32 or one of the two second suspension lead portions 222 of the second member 22. By this, the second wire 42 can be shaped such that the distance in the thickness direction z between the top of the second wire 42 closest to the top surface 51 and the insulating element 13 is as long as possible. This contributes to further improvement of the dielectric strength of the semiconductor device A1.

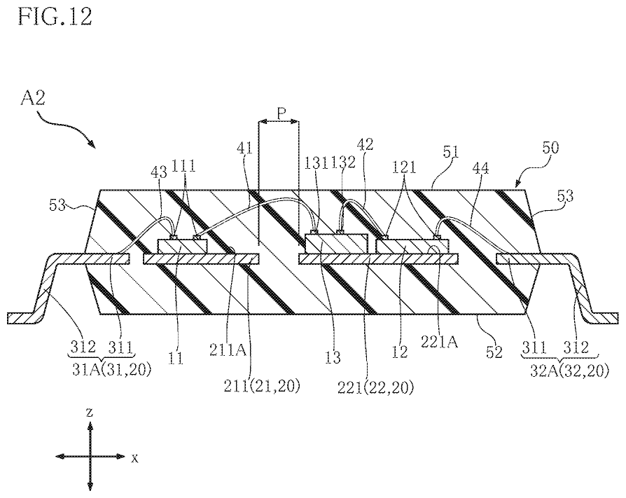

A semiconductor device A2 according to a second embodiment of the present disclosure is described below with reference to FIGS. 11 and 12. In these figures, the elements that are identical or similar to those of the semiconductor device A1 described above are denoted by the same reference signs, and the descriptions thereof are omitted. For convenience of understanding, the sealing resin 50 is transparent in FIG. 11. In FIG. 11 the outlines of the sealing resin 50 is shown by imaginary lines.

In the semiconductor device A2, the insulating element 13 is mounted in a manner different from the semiconductor device A1 described above.

As shown in FIGS. 11 and 12, the insulating element 13 is mounted on the second mounting surface 221A of the second island portion 221 of the second member 22. In the semiconductor device A2, the first wires 41 extend across the gap between the first island portion 211 of the first member 21 and the second island portion 221 of the second member 22. In this way, even if the potential of the second island portion 221 is higher than that of the first island portion 211, the insulating element 13 can be mounted on the second island portion 221.

The effect and advantages of the semiconductor device A2 are described below.

The semiconductor device A2 has the plurality of conductive members 20 including the first member 21 and the second member 22 and the sealing resin 50 covering a part of each of the conductive members 20. The voltage applied to the second member 22 differs from the voltage applied to the first member 21. The sealing resin 50 contains fillers 50B that are electrically insulating. The square cross section S in the sealing resin 50, which has a side length of ⅔ of the minimum spacing Pmin between two adjacent conductive members 20, contains at least portions of eight or more fillers 50B each having a particle size D equal to or greater than ⅛ of the minimum spacing Pmin. Thus, the semiconductor device A2 can also improve the dielectric strength. The semiconductor device A2 has a configuration in common with the semiconductor device A1, thereby achieving the same effect as the semiconductor device A1.

The present disclosure is not limited to the foregoing embodiments. The specific configuration of each part of the present disclosure can be varied in design in many ways.

The present disclosure includes the embodiments described in the following clauses.

Clause 1.

A semiconductor device comprising:
a plurality of conductive members including a first member and a second member;
a first semiconductor element electrically connected to one of the plurality of conductive members;
a second semiconductor element electrically connected to one of the plurality of conductive members and configured to receive input of a voltage different from a voltage applied to the first semiconductor element; and
a sealing resin covering a part of each of the plurality of conductive members, the first semiconductor element, and the second semiconductor element, wherein
a voltage applied to the second member differs from a voltage applied to the first member,
the sealing resin contains fillers that are electrically insulating, and
when a square cross section having a side length equal to ⅔ of a minimum spacing between two adjacent conductive members of the plurality of conductive members is hypothetically defined in the sealing resin,
eight or more of the fillers each having a particle size equal to or greater than ⅛ of the minimum spacing are at least partially contained in the square cross section.

Clause 2.

The semiconductor device according to clause 1, wherein a maximum particle size of the fillers is ½ of the minimum spacing.

Clause 3.

The semiconductor device according to clause 2, wherein the first member and the second member are spaced apart from each other in a first direction orthogonal to a thickness direction of each of the first semiconductor element and the second semiconductor element,
the first semiconductor element is mounted on the first member,
the second semiconductor element is mounted on the second member, and
a spacing between the first member and the second member is equal to or greater than 1.0 times and equal to or less than 3.0 times the minimum spacing.

Clause 4.

The semiconductor device according to clause 3, wherein the first semiconductor element is electrically connected to the first member.

Clause 5.

The semiconductor device according to clause 4, wherein the second semiconductor element is electrically connected to the second member.

Clause 6.

The semiconductor device according to any one of clauses 3 to 5, wherein the plurality of conductive members include a plurality of first terminals located on one side in the first direction and a plurality of second terminals located on the other side in the first direction,
the first semiconductor element is electrically connected to the plurality of first terminals, and
the second semiconductor element is electrically connected to the plurality of second terminals.

Clause 7.

The semiconductor device according to clause 6, wherein the plurality of first terminals and the plurality of second terminals are arranged along a second direction orthogonal to the first direction.

Clause 8.

The semiconductor device according to clause 7, wherein the first member includes a first island portion on which the first semiconductor element is mounted and two first suspension lead portions connected to opposite ends in the second direction of the first island portion, and
the two first suspension lead portions are exposed from one side of the sealing resin in the first direction.

Clause 9.

The semiconductor device according to clause 8, wherein the second member includes a second island portion on which the second semiconductor element is mounted and two second suspension lead portions connected to opposite ends in the second direction of the second island portion, and
the two second suspension lead portions are exposed from the other side of the sealing resin in the first direction.

Clause 10.

The semiconductor device according to clause 9, wherein the second island portion overlaps with the first island portion as viewed in the first direction.

Clause 11.

The semiconductor device according to any one of clauses 3 to 10, wherein the voltage applied to the second member is higher than the voltage applied to the first member.

Clause 12.

The semiconductor device according to any one of clauses 3 to 11, further comprising an insulating element that relays signals between the first semiconductor element and the second semiconductor element and insulates the first semiconductor element and the second semiconductor element from each other,
wherein the insulating element is of an inductive type.

Clause 13.

The semiconductor device according to clause 12, wherein the insulating element is mounted on the first member.

Clause 14.

The semiconductor device according to clause 12, wherein the insulating element is mounted on the second member.

Clause 15.

The semiconductor device according to any one of clauses 12 to 14, further comprising a first wire and a second wire, wherein
the first wire is bonded to the insulating element and the first semiconductor element,
the second wire is bonded to the insulating element and the second semiconductor element, and
composition of the first wire and the second wire includes gold.

Clause 16.

The semiconductor device according to any one of clauses 1 to 15, wherein composition of the fillers include silicon dioxide.

### REFERENCE NUMERALS

A1, A2: Semiconductor device
11: First semiconductor element
111: First electrode
12: Second semiconductor element
121: Second electrode
13: Insulating element
131: First relay electrode
132: Second relay electrode
20: Conductive member
21: First member
211: First island portion
211A: First mounting surface
212: First suspension lead portion
212A: Covered portion
212B: Exposed portion
213: Through-hole
22: Second member
221: Second island portion
221A: Second mounting surface
222: Second suspension lead portion
222A: Covered portion
222B: Exposed portion
31: First terminal
31A: First intermediate terminal
31B: First-side terminal
311: Covered portion
312: Exposed portion
32: Second terminal
32A: Second intermediate terminal
32B: Second-side terminal
321: Covered portion
322: Exposed portion
33: Metal layer
41: First wire
42: Second wire
43: Third wire
44: Fourth wire
45: Fifth wire
46: Sixth wire
50: Sealing resin
50A: Base material
50B: Filler
50C: Interface
51: Top surface
52: Bottom surface
53: First side surface
531: First upper portion
532: First lower portion
533: First intermediate portion
54: Second side surface
541: Second upper portion
542: Second lower portion
543: Second intermediate portion
Pmin: Minimum spacing
D: Particle size
S: Square cross section
P: Spacing
z: Thickness direction
x: First direction
y: Second direction

1. A semiconductor device comprising:
a plurality of conductive members including a first member and a second member;
a first semiconductor element electrically connected to one of the plurality of conductive members;
a second semiconductor element electrically connected to one of the plurality of conductive members and configured to receive input of a voltage different from a voltage applied to the first semiconductor element; and
a sealing resin covering a part of each of the plurality of conductive members, the first semiconductor element, and the second semiconductor element, wherein
a voltage applied to the second member differs from a voltage applied to the first member,
the sealing resin contains fillers that are electrically insulating, and
when a square cross section having a side length equal to ⅔ of a minimum spacing between two adjacent conductive members of the plurality of conductive members is hypothetically defined in the sealing resin,
eight or more of the fillers each having a particle size equal to or greater than ⅛ of the minimum spacing are at least partially contained in the square cross section.

2. The semiconductor device according to claim 1, wherein a maximum particle size of the fillers is ½ of the minimum spacing.

3. The semiconductor device according to claim 2, wherein the first member and the second member are spaced apart from each other in a first direction orthogonal to a thickness direction of each of the first semiconductor element and the second semiconductor element,
the first semiconductor element is mounted on the first member,
the second semiconductor element is mounted on the second member, and
a spacing between the first member and the second member is equal to or greater than 1.0 times and equal to or less than 3.0 times the minimum spacing.

4. The semiconductor device according to claim 3, wherein the first semiconductor element is electrically connected to the first member.

5. The semiconductor device according to claim 4, wherein the second semiconductor element is electrically connected to the second member.

6. The semiconductor device according to claim 3, wherein the plurality of conductive members include a plurality of first terminals located on one side in the first direction and a plurality of second terminals located on the other side in the first direction,
the first semiconductor element is electrically connected to the plurality of first terminals, and
the second semiconductor element is electrically connected to the plurality of second terminals.

7. The semiconductor device according to claim 6, wherein the plurality of first terminals and the plurality of second terminals are arranged along a second direction orthogonal to the first direction.

8. The semiconductor device according to claim 7, wherein the first member includes a first island portion on which the first semiconductor element is mounted and two first suspension lead portions connected to opposite ends in the second direction of the first island portion, and
the two first suspension lead portions are exposed from one side of the sealing resin in the first direction.

9. The semiconductor device according to claim 8, wherein the second member includes a second island portion on which the second semiconductor element is mounted and two second suspension lead portions connected to opposite ends in the second direction of the second island portion, and
the two second suspension lead portions are exposed from the other side of the sealing resin in the first direction.

10. The semiconductor device according to claim 9, wherein the second island portion overlaps with the first island portion as viewed in the first direction.

11. The semiconductor device according to claim 3, wherein the voltage applied to the second member is higher than the voltage applied to the first member.

12. The semiconductor device according to claim 3, further comprising an insulating element that relays signals between the first semiconductor element and the second semiconductor element and insulates the first semiconductor element and the second semiconductor element from each other,
wherein the insulating element is of an inductive type.

13. The semiconductor device according to claim 12, wherein the insulating element is mounted on the first member.

14. The semiconductor device according to claim 12, wherein the insulating element is mounted on the second member.

15. The semiconductor device according to claim 12, further comprising a first wire and a second wire, wherein
the first wire is bonded to the insulating element and the first semiconductor element,
the second wire is bonded to the insulating element and the second semiconductor element, and
composition of the first wire and the second wire includes gold.

16. The semiconductor device according to claim 1, wherein composition of the fillers include silicon dioxide.
